(19) United States
(12) Patent Application Publication
(10) Pub. No.: US 2026/0303041 A1
(43) Pub. Date: Oct. 1, 2026

(54) POWER AMPLIFIER MODULE

(71) Applicant: Murata Manufacturing Co., Ltd., Nagaokakyo-shi (JP)

(72) Inventor: Masatoshi HASE, Nagaokakyo-shi (JP)

(21) Appl. No.: 19/574,505

(22) Filed: Mar. 23, 2026

(30) Foreign Application Priority Data
Mar. 25, 2025 (JP) 2025-050241

(51) Int. Cl. H03F 3/21

(52) U.S. Cl. CPC H03F 3/21; H03F 2200/09; H03F 2200/451; H03F 2200/54

(57) ABSTRACT

Included are a first resistor, a first amplifier transistor having an emitter, a collector, and a base, the emitter being configured to receive a first signal, the first signal and a second signal being differential signals, the collector being configured to output a first output signal, the base being configured to receive a bias through the first resistor, a second resistor, a second amplifier transistor having an emitter, a collector, and a base, the emitter being configured to receive the second signal, the collector being configured to output a second output signal, the base being configured to receive a bias through the second resistor, and a capacitor, one end of the capacitor being electrically connected to the base of the first amplifier transistor, and another end of the capacitor being electrically connected to the base of the second amplifier transistor.

### CROSS REFERENCE TO RELATED APPLICATION

This application claims priority from Japanese Patent Application No. 2025-050241, filed on Mar. 25, 2025. The content of this application is incorporated herein by reference in its entirety.

### BACKGROUND OF THE DISCLOSURE

### 1. Field of the Disclosure

The present disclosure relates to power amplifier modules.

### 2. Description of the Related Art

A power amplifier module that provides amplification in multiple stages to obtain desired gains is disclosed (see U.S. Pat. No. 10,658,991).

### BRIEF SUMMARY OF THE DISCLOSURE

The power amplifier module described in U.S. Pat. No. 10,658,991 amplifies radio-frequency signals using an amplifier transistor in a common-base configuration provided in a driver stage. The power amplifier module further amplifies the amplified radio-frequency signal using an amplifier transistor in a power stage and outputs an output signal. In the power amplifier module, since an amplifier transistor in a common-base configuration is used, it is necessary to provide AC grounding for the base. Accordingly, a capacitor is provided between the base of the amplifier transistor in the common-base configuration and ground. However, when an operating frequency of the amplifier transistor in the common-base configuration is low, it is necessary to increase the capacitor, which leads to a problem of an increase in size of the power amplifier module.

Accordingly, a possible benefit of the present disclosure is to suppress an increase in size of the power amplifier module that includes amplifier transistors in a common-base configuration.

A power amplifier module according to one aspect of the present disclosure includes a first resistor, a first amplifier transistor having an emitter, a collector, and a base, the emitter being configured to receive a first signal, the first signal and a second signal being differential signals, the collector being configured to output a first output signal, the base being configured to receive a bias through the first resistor, a second resistor, a second amplifier transistor having an emitter, a collector, and a base, the emitter being configured to receive the second signal, the collector being configured to output a second output signal, the base being configured to receive a bias through the second resistor, and a capacitor, one end of the capacitor being electrically connected to the base of the first amplifier transistor, and another end of the capacitor being electrically connected to the base of the second amplifier transistor, the capacitor being connected in parallel with the first resistor and the second resistor.

The present disclosure suppresses an increase in size of the power amplifier module that includes an amplifier transistor in a common-base configuration.

### BRIEF DESCRIPTION OF THE SEVERAL VIEWS OF THE DRAWINGS

FIG. 1 illustrates an example of the configuration of a power amplifier module according to the present embodiment;

FIG. 2 illustrates an example of the configuration of parallel-connected amplifier circuits according to the present embodiment;

FIG. 3 illustrates an example of the configuration of a power amplifier module according to a first modification;

FIG. 4 illustrates an example of the configuration of a power amplifier module according to a second modification;

FIG. 5 illustrates an example of the configuration of a power amplifier module according to a third modification;

FIG. 6 illustrates an example of the configuration of a power amplifier module according to a fourth modification;

FIG. 7 illustrates an example of the configuration of a power amplifier module according to a fifth modification; and

FIG. 8 illustrates an example of the layout of the elements of the power amplifier module.

### DETAILED DESCRIPTION OF THE DISCLOSURE

Hereinafter, preferred embodiments of the present disclosure will be described with reference to the drawings. Circuit elements with the same reference numerals refer to the same circuit elements, and redundant descriptions thereof are omitted.

### Configuration of Power Amplifier Module 100

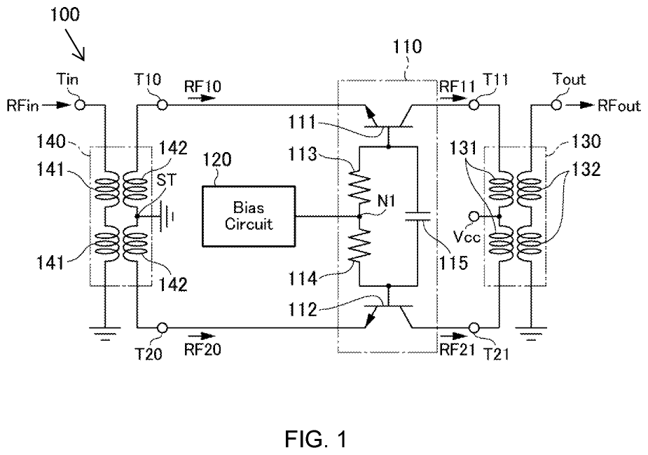

Referring to FIG. 1, an overview of the power amplifier module 100 according to the present embodiment is described. FIG. 1 illustrates an overview of the configuration of the power amplifier module 100 according to the present embodiment. The power amplifier module 100 may be installed in, for example, mobile communication devices such as mobile phones. The power amplifier module 100 amplifies the power of an input signal RFin to a level necessary for transmission to a base station and outputs the amplified signal as an output signal RFout. The input signal RFin is a radio-frequency (RF) signal modulated according to a predetermined communication scheme, for example, by a radio-frequency integrated circuit (RFIC). Examples of the communication standards for the input signal RFin include second generation (2G) mobile communication system, third generation (3G) mobile communication system, fourth generation (4G) mobile communication system, fifth-generation (5G) mobile communication system, 5G New Radio (NR), Long Term Evolution (LTE)-frequency division duplex (FDD), LTE-time division duplex (TDD), LTE-Advanced or LTE-Advanced pro, and sixth-generation (6G) mobile communication system. The frequency of the input signal RFin may range, for example, from several hundred MHz to several tens of GHz. The communication standards and the frequency of the input signal RFin are not limited to these examples.

Referring to FIG. 1, an overview of the power amplifier module 100 will be described. As illustrated in FIG. 1, the power amplifier module 100 includes amplifier transistors 111 and 112, which are bipolar transistors in a common-base configuration. In the power amplifier module 100, the differential signals outputted from a converter 140 are amplified by the amplifier transistors 111 and 112. In the power amplifier module 100, a capacitor 115 is provided between the bases of the amplifier transistors 111 and 112. As a result, in the power amplifier module 100, the capacitor 115 enables both the bases of the amplifier transistors 111 and 112 to be virtually AC-grounded, which reduces the capacitance of the capacitor for AC grounding, thereby suppressing an increase in size of the circuit.

In the following description, the signal inputted to the amplifier transistor 111 is referred to as a first signal RF10, and the signal inputted to the amplifier transistor 112 is referred to as a second signal RF20.

In the power amplifier module 100, the center tap of a secondary coil 142 of the converter 140, which outputs differential signals, is electrically grounded. The emitters of the amplifier transistors 111 and 112 in the common-base configuration are electrically connected to the converter 140. This means that the emitters of the amplifier transistors 111 and 112 are electrically grounded. As a result, in the power amplifier module 100, since the emitters of the amplifier transistors 111 and 112 are DC-connected via the converter 140, there is no need to provide any LC parallel resonant circuit, thereby suppressing an increase in size of the circuit.

Additionally, in the power amplifier module 100, a first resistor 113 is electrically connected to the base of the amplifier transistor 111, and a second resistor 114 is electrically connected to the base of the amplifier transistor 112. A bias is configured to be supplied to the node between the first resistor 113 and the second resistor 114. In this configuration, in the power amplifier module 100, the bases of the amplifier transistors 111 and 112, which are bipolar transistors, are electrically connected to each other through the resistors. This configuration can avoid non-uniform operation due to coupling resulting from self-heating of the bipolar transistors.

Referring to FIG. 1, the configuration of the power amplifier module 100 is described. As illustrated in FIG. 1, the power amplifier module 100 includes an amplifier circuit 110, a bias circuit 120, an output circuit 130, and the converter 140.

The amplifier circuit 110 is a circuit configured to amplify the first signal RF10 and the second signal RF20 and to output a first output signal RF11 and a second output signal RF21. The amplifier circuit 110 includes, for example, the amplifier transistor 111, the amplifier transistor 112, the first resistor 113, the second resistor 114, and the capacitor 115.

The amplifier transistor 111 is a bipolar transistor configured in a common-base configuration. In the amplifier transistor 111, the first signal RF10 is inputted to the emitter, the first output signal RF11 is outputted from the collector, and a bias is supplied from the bias circuit 120 to the base through the first resistor 113.

The amplifier transistor 112 is a bipolar transistor configured in a common-base configuration. In the amplifier transistor 112, the second signal RF20 is inputted to the emitter, the second output signal RF21 is outputted from the collector, and a bias is supplied from the bias circuit 120 to the base through the second resistor 114.

The first resistor 113 is, for example, a resistive element. One end of the first resistor 113 is electrically connected to the base of the amplifier transistor 111, and the other end of the first resistor 113 is electrically connected to a node N1.

The second resistor 114 is, for example, a resistive element. One end of the second resistor 114 is electrically connected to the base of the amplifier transistor 112, and the other end of the second resistor 114 is electrically connected to the node N1.

The amplifier circuit 110 is configured to receive a bias from the bias circuit 120 at the bases of the amplifier transistors 111 and 112 through the respective resistive elements. This configuration can suppress self-heating of the amplifier transistors 111 and 112. When self-heating occurs in the amplifier circuit 110, the operation of the circuit can become non-uniform. The power amplifier module 100 can thus avoid non-uniform operation of the circuit by suppressing self-heating in the amplifier circuit 110.

One end of the capacitor 115 is electrically connected to the base of the amplifier transistor 111, and the other end of the capacitor 115 is electrically connected to the base of the amplifier transistor 112.

Since the capacitor 115 is provided in the amplifier circuit 110, the bases of the amplifier transistors 111 and 112 are virtually AC-grounded via the capacitor 115. This configuration enables the power amplifier module 100 to reduce the total capacitance of the capacitor for AC grounding in the module, thereby suppressing an increase in size of the circuit.

The bias circuit 120 is a circuit configured to supply a bias to the amplifier circuit 110.

The output circuit 130 is a circuit configured to combine the first output signal RF11 and the second output signal RF21 outputted from the amplifier circuit 110 and to output the output signal RFout from a terminal Tout. The output circuit 130 is, for example, a balun composed of a primary coil 131 and a secondary coil 132 that is magnetically coupled with the primary coil 131. A terminal T11 at one end of the primary coil 131 is configured to receive the first output signal RF11, a terminal T21 at the other end of the primary coil 131 is configured to receive the second output signal RF21, and the center tap of the primary coil 131 is configured to receive power Vcc. One end of the secondary coil 132 is electrically grounded, and a terminal Tout at the other end of the secondary coil 132 is configured to output the output signal RFout. The output circuit 130 is not necessarily provided. This means that the power amplifier module 100 may output the first output signal RF11 and the second output signal RF21, which are differential signals, to a differential amplifier circuit in a subsequent stage.

The converter 140 receives the input signal RFin and outputs the first signal RF10 and the second signal RF20, which are differential signals, to the amplifier circuit 110. The converter 140 is, for example, a balun composed of a primary coil 141 and a secondary coil 142 that is magnetically coupled with the primary coil 141. A terminal Tin at one end of the primary coil 141 is configured to receive the input signal RFin, and the other end of the primary coil 141 is electrically grounded. The secondary coil 142 outputs the first signal RF10 from a terminal T10 at one end and the second signal RF20 from a terminal T20 at the other end, and the center tap St is electrically grounded. The impedance in the converter 140 can be transformed by changing the ratio of turns of the primary coil 141 to the secondary coil 142.

In the power amplifier module 100, the center tap St of the secondary coil 142 of the converter 140 is electrically grounded. This configuration enables the emitters of the amplifier transistors 111 and 112 to be DC-grounded. This configuration avoids the need to provide an LC parallel resonant circuit for the amplifier transistors 111 and 112 in the power amplifier module 100, thereby suppressing an increase in size of the circuit.

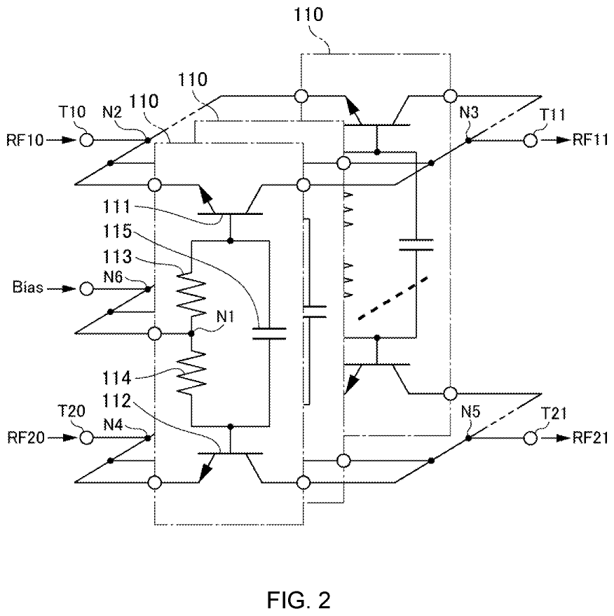

Next, referring to FIG. 2, the configuration of multiple amplifier circuits 110 connected in parallel in the power amplifier module 100 is described.

As illustrated in FIG. 2, the power amplifier module 100 may be configured by connecting multiple amplifier circuits 110 in parallel. In this case, in the multiple amplifier circuits 110, the emitters of the amplifier transistors 111 are electrically connected together at a node N2, and the collectors of the amplifier transistors 111 are electrically connected to a node N3. In this case, in the multiple amplifier circuits 110, the emitters of the amplifier transistors 112 are electrically connected to a node N4, and the collectors of the amplifier transistors 111 are electrically connected to a node N5. Furthermore, each node N1 between the first resistor 113 and the second resistor 114 in the multiple amplifier circuits 110 is electrically connected to a node N6.

With this configuration, in the power amplifier module 100, a bias is supplied by the bias circuit 120 to the base of each amplifier transistor 111 in the multiple amplifier circuits 110 through the corresponding first resistor 113. Similarly, a bias is supplied by the bias circuit 120 to the base of each amplifier transistor 112 in the multiple amplifier circuits 110 through the corresponding second resistor 114.

In other words, in the power amplifier module 100, the bases of the multiple amplifier transistors 111 are electrically connected together via the corresponding first resistors 113. In this case, when one of the amplifier transistors 111 of the multiple amplifier circuits 110 generates heat, the base-emitter voltage Vbe of the amplifier transistor 111 decreases, resulting in non-uniform operation with excessive current flow; however, the current can be returned to a normal value by the voltage drop due to the first resistor 113. The same applies to multiple amplifier transistors 112 and corresponding second resistors 114.

This configuration enables the power amplifier module 100 to suppress non-uniform operation.

### First Modification

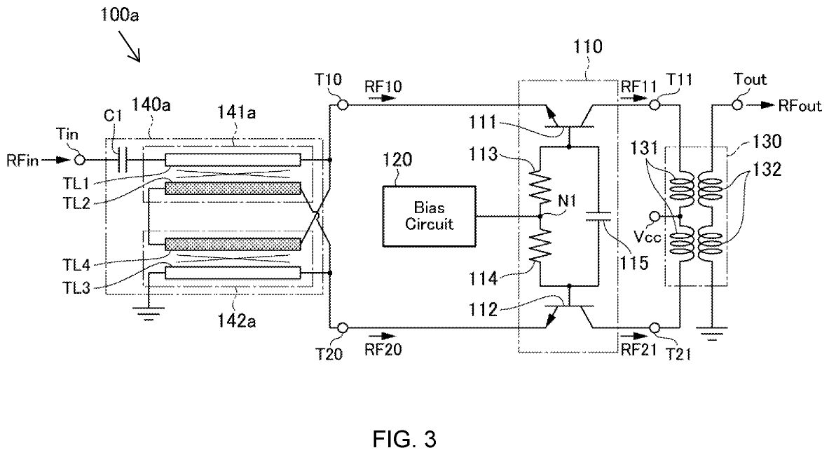

Next, referring to FIG. 3, the configuration of a power amplifier module 100a according to a first modification is described. FIG. 3 illustrates an example of the configuration of the power amplifier module 100a according to the first modification. The power amplifier module 100a differs from the power amplifier module 100 in the configuration of the converter 140. In the following, the same descriptions as described for the power amplifier module 100 apply, unless otherwise specified.

As illustrated in FIG. 3, a converter 140a includes a first transmission line transformer 141a and a second transmission line transformer 142a, in which a balun is formed by the first transmission line transformer 141a and the second transmission line transformer 142a. The converter 140a is, for example, a balun using Guanella transmission line transformers (TLTs).

The first transmission line transformer 141a is a transformer operable to perform impedance transformation. The first transmission line transformer 141a includes a first transmission line TL1 and a second transmission line TL2. One end of the first transmission line TL1 is configured to receive the input signal RFin through a capacitor C1, and the other end of the first transmission line TL1 is electrically connected to the emitter of the amplifier transistor 111. The second transmission line TL2 is magnetically coupled to the first transmission line TL1. One end of the second transmission line TL2 is electrically connected to the emitter of the amplifier transistor 112. Although in FIG. 3 the first transmission line TL1 and the second transmission line TL2 are each illustrated as being formed by a single transmission line, this should not be interpreted as limiting. For example, each of the first transmission line TL1 and the second transmission line TL2 may be formed by multiple transmission lines. This means that the first transmission line transformer 141a is configured to allow the impedance transformation ratio to be adjusted.

The second transmission line transformer 142a is a transformer operable to perform impedance transformation. The second transmission line transformer 142a includes a third transmission line TL3 and a fourth transmission line TL4. One end of the third transmission line TL3 is electrically grounded, and the other end of the third transmission line TL3 is electrically connected to the emitter of the amplifier transistor 112. The fourth transmission line TL4 is magnetically coupled to the third transmission line TL3. One end of the fourth transmission line TL4 is electrically connected to the other end of the second transmission line TL2, and the other end of the fourth transmission line TL4 is electrically connected to the emitter of the amplifier transistor 111. Although in FIG. 3 the third transmission line TL3 and the fourth transmission line TL4 are each illustrated as being formed by a single transmission line, this should not be interpreted as limiting. For example, each of the first transmission line TL1 and the second transmission line TL2 may be formed by multiple transmission lines. This means that the second transmission line transformer 142a is configured to allow the impedance transformation ratio to be adjusted.

As described above, since in the power amplifier module 100a the converter 140a is electrically grounded, there is no need to provide an LC parallel resonant circuit in the amplifier circuit 110. This configuration suppresses an increase in size of the circuit in the power amplifier module 100a.

Furthermore, since the number of transmission lines in each of the first transmission line TL1 to the fourth transmission line TL4 is adjustable such that the impedance transformation ratio is adjustable, the power amplifier module 100a can be used in a wider range of applications.

Moreover, since the power amplifier module 100a uses transmission line transformers, the power amplifier module 100a can be used for signals at higher frequencies and over a wider frequency range than the power amplifier module 100.

### Second Modification

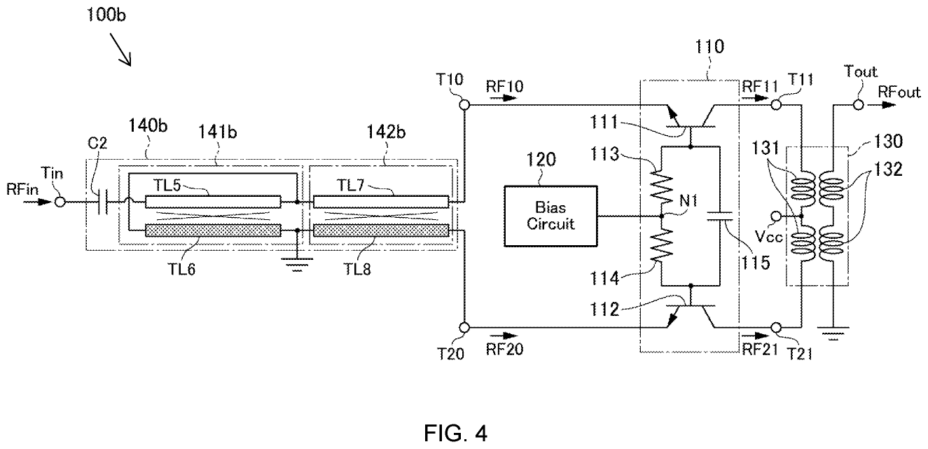

Next, referring to FIG. 4, the configuration of a power amplifier module 100b according to a second modification is described. FIG. 4 illustrates an example of the configuration of the power amplifier module 100b according to the second modification. The power amplifier module 100b differs from the power amplifier module 100 in the configuration of the converter 140. In the following, the same descriptions as described for the power amplifier module 100 apply, unless otherwise specified.

As illustrated in FIG. 4, the converter 140b includes a third transmission line transformer 141b and a balun 142b.

The third transmission line transformer 141b is a transformer operable to perform impedance transformation. The third transmission line transformer 141b includes a fifth transmission line TL5 and a sixth transmission line TL6. One end of the fifth transmission line TL5 is configured to receive the input signal RFin through a capacitor C2. One end of the sixth transmission line TL6 is electrically connected to the other end of the fifth transmission line TL5, and the other end of the sixth transmission line TL6 is electrically grounded. That is, the third transmission line transformer 141b is an Unun using a Ruthroff TLT. Although in FIG. 4 the fifth transmission line TL5 and the sixth transmission line TL6 are each illustrated as being formed by a single transmission line, this should not be interpreted as limiting. For example, each of the fifth transmission line TL5 and the sixth transmission line TL6 may be formed by multiple transmission lines. This means that the third transmission line transformer 141b is configured to allow the impedance transformation ratio to be adjusted.

The balun 142b outputs the first signal RF10 and the second signal RF20. The balun 142b includes a seventh transmission line TL7 and an eighth transmission line TL8. One end of the seventh transmission line TL7 is electrically connected to the other end of the fifth transmission line TL5, and the other end of the seventh transmission line TL7 is electrically connected to the emitter of the amplifier transistor 111. The first signal RF10 is outputted from the other end of the seventh transmission line TL7 to the emitter of the amplifier transistor 111. One end of the eighth transmission line TL8 is electrically connected to the other end of the sixth transmission line TL6 and to ground, and the other end of the eighth transmission line TL8 is electrically connected to the emitter of the amplifier transistor 112. The eighth transmission line TL8 is magnetically coupled to the seventh transmission line TL7. That is, the balun 142b is a balun using a common mode choke (CMC). Although in FIG. 4 the seventh transmission line TL7 and the eighth transmission line TL8 are each illustrated as being formed by a single transmission line, this should not be interpreted as limiting. For example, each of the seventh transmission line TL7 and the eighth transmission line TL8 may be formed by multiple transmission lines. This means that the balun 142b is configured to allow the impedance transformation ratio to be adjusted.

As described above, since in the power amplifier module 100b the converter 140b is electrically grounded, there is no need to provide an LC parallel resonant circuit in the amplifier circuit 110. This configuration suppresses an increase in size of the circuit in the power amplifier module 100a.

Furthermore, since the number of transmission lines in each of the fifth transmission line TL5 to the eighth transmission line TL8 is adjustable such that the impedance transformation ratio is adjustable, the power amplifier module 100b can be used in a wider range of applications.

Moreover, since the power amplifier module 100b uses transmission line transformers, the power amplifier module 100b can be used for signals at higher frequencies and over a wider frequency range than the power amplifier module 100.

### Third Modification

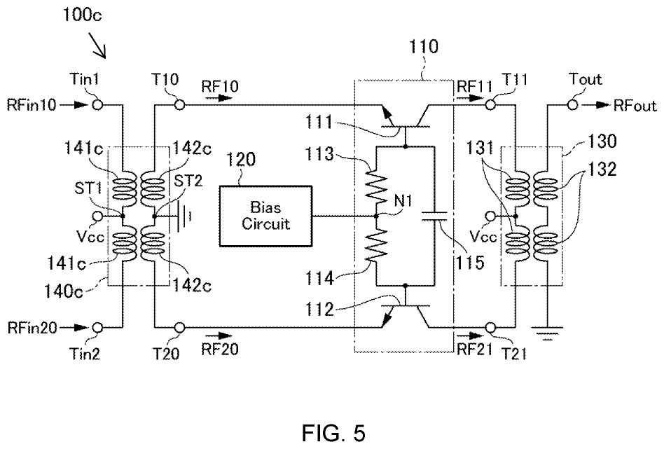

Next, referring to FIG. 5, the configuration of a power amplifier module 100c according to a third modification is described. FIG. 5 illustrates an example of the configuration of the power amplifier module 100c according to the third modification. The power amplifier module 100c differs from the power amplifier module 100 in that the input signal inputted to the converter 140 is a differential signal. In the following, the same descriptions as described for the power amplifier module 100 apply, unless otherwise specified.

As illustrated in FIG. 5, a converter 140c receives, as input signals, a first input signal RFin10 and a second input signal RFin20, which are differential signals. The converter 140c, for example, performs impedance transformation and outputs the first signal RF10 and the second signal RF20.

The converter 140c includes a primary coil 141c and a secondary coil 142c. A terminal Tin1 at one end of the primary coil 141c is configured to receive the first input signal RFin10, a terminal Tin2 at the other end of the primary coil 141c is configured to receive the second input signal RFin20, and a center tap St1 of the primary coil 141c is configured to receive power Vcc. The secondary coil 142c outputs the first signal RF10 from a terminal T10 at one end and the second signal RF20 from a terminal T20 at the other end, and a center tap St2 is electrically grounded. It includes a secondary coil. The secondary coil 142c is magnetically coupled to the primary coil 141c. The impedance in the converter 140c can be transformed by changing the ratio of turns of the primary coil 141c to the secondary coil 142c.

As described above, since in the power amplifier module 100c the converter 140c is electrically grounded, there is no need to provide an LC parallel resonant circuit in the amplifier circuit 110. This configuration suppresses an increase in size of the circuit in the power amplifier module 100c.

Furthermore, in the power amplifier module 100c, a differential amplifier circuit similar to the amplifier circuit 110 can be directly connected to the primary coil 141c of the converter 140c. This configuration can increase the gain of the entire module.

### Fourth Modification

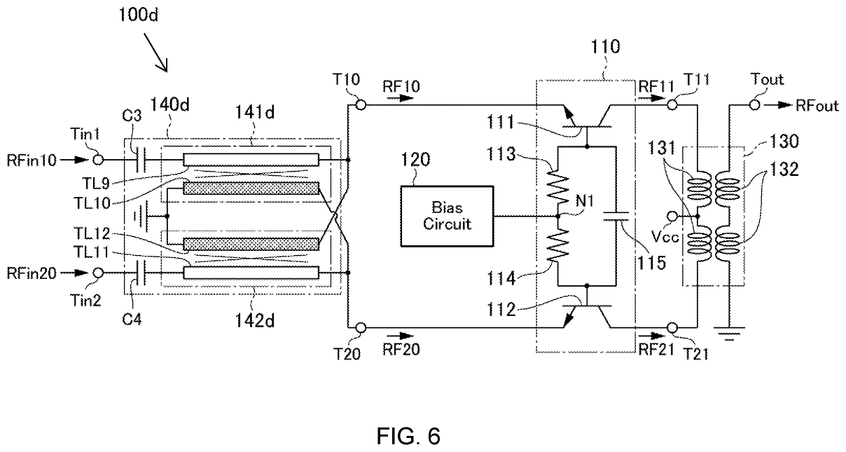

Next, referring to FIG. 6, the configuration of a power amplifier module 100d according to a fourth modification is described. FIG. 6 illustrates an example of the configuration of the power amplifier module 100d according to the fourth modification. The power amplifier module 100d differs from the power amplifier module 100 in that the input signal inputted to the converter 140 is a differential signal, and a configuration corresponding thereto is used. In the following, the same descriptions as described for the power amplifier module 100 apply, unless otherwise specified.

As illustrated in FIG. 6, a converter 140d receives, as input signals, the first input signal RFin10 and the second input signal RFin20, which are differential signals, respectively through terminals Tin1 and Tin2. The converter 140d, for example, performs impedance transformation and outputs the first signal RF10 and the second signal RF20.

The converter 140d is, for example, a transformer using a Guanella TLT. Specifically, the converter 140d includes a fourth transmission line transformer 141d and a fifth transmission line transformer 142d.

The fourth transmission line transformer 141d is a transformer operable to perform impedance transformation. The fourth transmission line transformer 141d includes a ninth transmission line TL9 and a tenth transmission line TL10. One end of the ninth transmission line TL9 is configured to receive a first input signal RFin10 through a capacitor C10, and the other end of the ninth transmission line TL9 is electrically connected to the emitter of the amplifier transistor 111. One end of the tenth transmission line TL10 is electrically connected to the emitter of the amplifier transistor 112, and the other end of the tenth transmission line TL10 is electrically grounded. The tenth transmission line TL10 is magnetically coupled to the ninth transmission line TL9.

The fifth transmission line transformer 142d is a transformer operable to perform impedance transformation. The fifth transmission line transformer 142d includes an eleventh transmission line TL11 and a twelfth transmission line TL12. One end of the eleventh transmission line TL11 is configured to receive a second input signal RFin20 through a capacitor C20, and the other end of the eleventh transmission line TL11 is electrically connected to the emitter of the amplifier transistor 112 and to ground. One end of the twelfth transmission line TL12 is electrically connected to the other end of the tenth transmission line, and the other end of the twelfth transmission line TL12 is electrically connected to the emitter of the amplifier transistor 111. The twelfth transmission line TL12 is magnetically coupled to the eleventh transmission line TL11.

As described above, since in the power amplifier module 100d the converter 140d is electrically grounded, there is no need to provide an LC parallel resonant circuit in the amplifier circuit 110. This configuration suppresses an increase in size of the circuit in the power amplifier module 100d.

Furthermore, since the number of transmission lines in each of the ninth transmission line TL9 to the twelfth transmission line TL12 is adjustable such that the impedance transformation ratio is adjustable, the power amplifier module 100d can be used in a wider range of applications.

Moreover, since the power amplifier module 100d uses transmission line transformers, the power amplifier module 100d can be used for signals at higher frequencies and over a wider frequency range than the power amplifier module 100.

Furthermore, in the power amplifier module 100d, a differential amplifier circuit similar to the amplifier circuit 110 can be directly connected to the primary side of the converter 140d. This configuration can increase the gain of the entire module.

### Fifth Modification

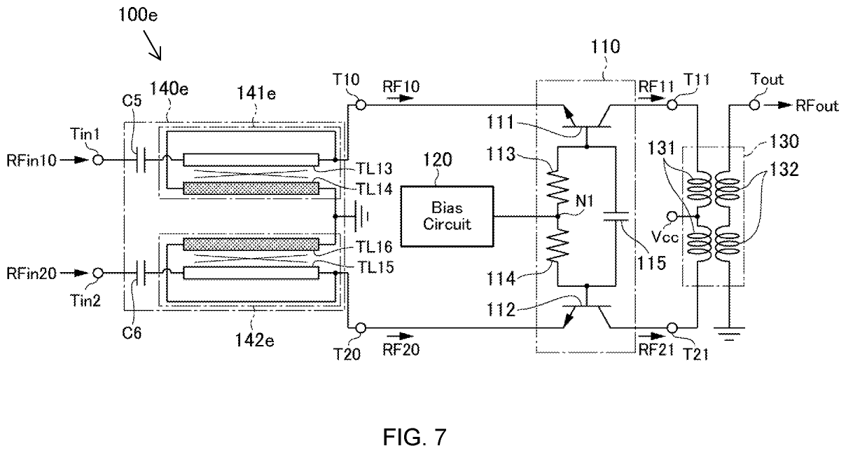

Next, referring to FIG. 7, the configuration of a power amplifier module 100e according to a fifth modification is described. FIG. 7 illustrates an example of the configuration of the power amplifier module 100e according to the fifth modification. The power amplifier module 100e differs from the power amplifier module 100 in that the input signal inputted to the converter 140 is a differential signal, and a configuration corresponding thereto is used. In the following, the same descriptions as described for the power amplifier module 100 apply, unless otherwise specified.

As illustrated in FIG. 7, a converter 140e receives, as input signals, the first input signal RFin10 and the second input signal RFin20, which are differential signals, respectively through terminals Tin1 and Tin2. The converter 140e, for example, performs impedance transformation and outputs the first signal RF10 and the second signal RF20.

The converter 140e is, for example, a transformer using a Ruthroff TLT. Specifically, the converter 140e includes a sixth transmission line transformer 141e and a seventh transmission line transformer 142e.

The sixth transmission line transformer 141e is a transformer operable to perform impedance transformation. The sixth transmission line transformer 141e includes a thirteenth transmission line TL13 and a fourteenth transmission line TL14. One end of the thirteenth transmission line TL13 is configured to receive the first input signal RFin10 through a capacitor C5. One end of the fourteenth transmission line TL14 is electrically connected to the other end of the thirteenth transmission line TL13, and the other end of the fourteenth transmission line TL14 is electrically grounded. The fourteenth transmission line TL14 is magnetically coupled to the thirteenth transmission line TL13.

The seventh transmission line transformer 142e is a transformer operable to perform impedance transformation. The seventh transmission line transformer 142e includes a fifteenth transmission line TL15 and a sixteenth transmission line TL16. One end of the fifteenth transmission line TL15 is configured to receive the second input signal RFin20 through a capacitor C6. One end of the sixteenth transmission line TL16 is electrically connected to the other end of the fifteenth transmission line TL15, and the other end of the sixteenth transmission line TL16 is electrically connected to the other end of the fourteenth transmission line TL14 and to ground.

As described above, since in the power amplifier module 100e the converter 140e is electrically grounded, there is no need to provide an LC parallel resonant circuit in the amplifier circuit 110. This configuration suppresses an increase in size of the circuit in the power amplifier module 100e.

Furthermore, since the number of transmission lines in each of the thirteenth transmission line TL13 to the sixteenth transmission line TL16 is adjustable such that the impedance transformation ratio is adjustable, the power amplifier module 100e can be used in a wider range of applications.

Moreover, since the power amplifier module 100e uses transmission line transformers, the power amplifier module 100e can be used for signals at higher frequencies and over a wider frequency range than the power amplifier module 100.

Furthermore, in the power amplifier module 100e, a differential amplifier circuit similar to the amplifier circuit 110 can be directly connected to the primary side of the converter 140e. This configuration can increase the gain of the entire module.

### Layout

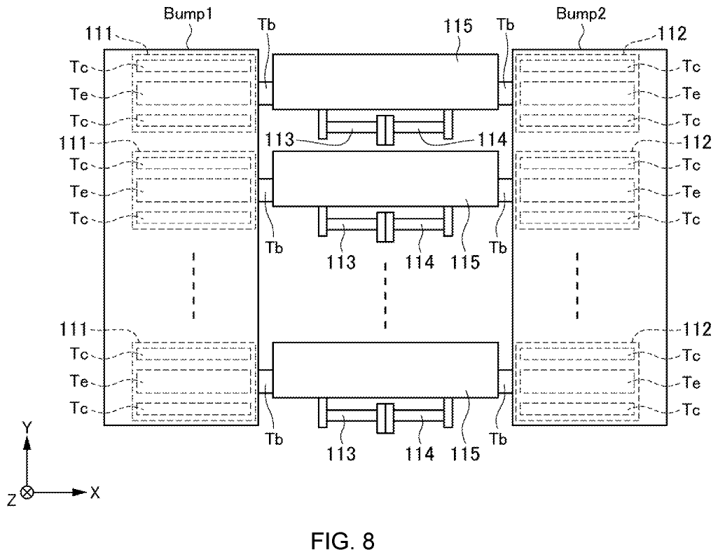

Next, referring to FIG. 8, an example of the layout of the elements of the power amplifier module 100 is described. FIG. 8 illustrates an example of the layout of the elements of the power amplifier module 100. In the following, the directions along the major surface of the substrate are defined as the X direction and Y direction, and the direction orthogonal to the X direction and the Y direction is defined as the Z direction. The view in the Z direction is referred to as “plan view.”

FIG. 8 illustrates the power amplifier module 100 in which multiple amplifier circuits 110 are connected in parallel. In FIG. 8, the multiple amplifier circuits 110 are arranged along the Y direction in plan view. Specifically, multiple amplifier transistors 111 are arranged in a line along the Y direction. Similarly, multiple amplifier transistors 112 are arranged in a line along the Y direction. For example, the amplifier transistors 111 and 112 are arranged such that the center lines extending along the Y direction of the amplifier transistors 111 are aligned with each other, and the center lines extending along the Y direction of the amplifier transistors 112 are aligned with each other.

The amplifier transistors 111 and 112 are symmetrically arranged in the X direction across the capacitor 115 in plan view. Specifically, the amplifier transistors 111 are arranged such that the length of the extension of the base Tb toward the capacitor 115 is minimized. For example, for each amplifier transistor 111, the base Tb is provided between the emitter Te and the collector Tc (the emitter Te in FIG. 8) and the capacitor 115. Each amplifier transistor 112 is arranged in the same manner.

At least a portion of the emitter and the collector of each amplifier transistor 111 overlaps with a first bump Bump1 in plan view. At least a portion of the emitter and the collector of each amplifier transistor 112 overlaps with a second bump Bump2 in plan view. For example, the collectors of the amplifier transistors 111 are electrically connected to the first bump Bump1. For example, the collectors of the amplifier transistors 112 are electrically connected to the second bump Bump2. This means that the first bump Bump1 functions as a lead terminal for outputting the first output signal RF11, and the second bump Bump2 functions as a lead terminal for outputting the second output signal RF21.

This configuration minimizes the interconnection length of each of the emitter, base, and collector of the amplifier transistors 111 and 112 in the power amplifier module 100, thereby improving the characteristics of the module.

### Conclusion

<1> The power amplifier module 100 according to the present embodiment comprising: the first resistor 113; the amplifier transistor 111 (a first amplifier transistor) having an emitter, a collector, and a base, the emitter being configured to receive the first signal RF10, the first signal RF10 and the second signal RF20 being differential signals, the collector being configured to output the first output signal RF11, the base being configured to receive a bias through the first resistor 113; the second resistor 114; the amplifier transistor 112 (a second amplifier transistor) having an emitter, a collector, and a base, the emitter being configured to receive the second signal RF20, the collector being configured to output the second output signal, the base being configured to receive a bias through the second resistor 114; and the capacitor 115, one end of the capacitor 115 being electrically connected to the base of the amplifier transistor 111 (the first amplifier transistor), and another end of the capacitor 115 being electrically connected to the base of the amplifier transistor 112 (the second amplifier transistor), the capacitor 115 being connected in parallel with the first resistor 113 and the second resistor 114. This configuration enables a reduction in size of the capacitor 115 for virtual grounding in the power amplifier module 100.
<2> The power amplifier module according to <1>, the power amplifier module 100 according to the present embodiment, wherein the amplifier transistor 111 (the first amplifier transistor) includes a plurality of transistors connected in parallel, each of the transistors of the amplifier transistor 111 (the first amplifier transistor) has an emitter, a collector, and a base, the emitter being configured to receive the first signal RF10, the collector being configured to output the first output signal RF11, the base being configured to receive the bias through the first resistor 113, and the amplifier transistor 112 (the second amplifier transistor) includes a plurality of transistors connected in parallel, each of the transistors of the amplifier transistor 112 (the second amplifier transistor) has an emitter, a collector, and a base, the emitter being configured to receive the second signal RF20, the collector being configured to output the second output signal RF21, the base being configured to receive the bias through the second resistor 114. This configuration enables the power amplifier module 100 to suppress non-uniform operation.
<3> The power amplifier module according to <1> or <2>, the power amplifier module 100 according to the present embodiment, further comprising: the converter 140 (a first balun) including the primary coil 141 and the secondary coil 142, the primary coil 141 being configured to receive an input signal, the secondary coil 142 being magnetically coupled to the primary coil 141, the secondary coil 142 having a center tap that is electrically connected to a reference potential, the secondary coil 142 being configured to output the first signal RF10 to the emitter of the amplifier transistor 111 (the first amplifier transistor) and to output the second signal RF20 to the emitter of the amplifier transistor 112 (the second amplifier transistor). This configuration avoids the need to provide an LC parallel resonant circuit for the amplifier transistors 111 and 112 in the power amplifier module 100, thereby suppressing an increase in size of the circuit.
<4> The power amplifier module according to <1> or <2>, the power amplifier module 100a according to the present embodiment, further comprising: the converter 140a including the first transmission line transformer 141a and the second transmission line transformer 142a, the converter 140a being configured to output the first signal RF10 to the emitter of the amplifier transistor 111 (the first amplifier transistor) and to output the second signal RF20 to the emitter of the amplifier transistor 112 (the second amplifier transistor), the first transmission line transformer 141a including the first transmission line TL1 and the second transmission line TL2, one end of the first transmission line TL1 being configured to receive an input signal, and another end of the first transmission line TL1 being electrically connected to the emitter of the amplifier transistor 111 (the first amplifier transistor), the second transmission line TL2 being magnetically coupled to the first transmission line TL1, one end of the second transmission line TL2 being electrically connected to the emitter of the amplifier transistor 112 (the second amplifier transistor), the second transmission line transformer 142a including the third transmission line TL3 and the fourth transmission line TL4, one end of the third transmission line TL3 being electrically connected to a reference potential, and another end of the third transmission line TL3 being electrically connected to the emitter of the amplifier transistor 112 (the second amplifier transistor), one end of the fourth transmission line TL4 being electrically connected to another end of the second transmission line TL2, and another end of the fourth transmission line TL4 being electrically connected to the emitter of the amplifier transistor 111 (the first amplifier transistor). This configuration enables a reduction in size of the circuit in the power amplifier module 100a, enables the power amplifier module 100a to be used at higher frequencies over wider frequency ranges, and enables impedance transformation by the power amplifier module 100a.
<5> The power amplifier module according to <1> or <2>, the power amplifier module 100b according to the present embodiment, further comprising: the third transmission line transformer 141b including the fifth transmission line TL5 and the sixth transmission line TL6, one end of the fifth transmission line TL5 being configured to receive an input signal, one end of the sixth transmission line TL6 being electrically connected to another end of the fifth transmission line TL5, and another end of the sixth transmission line TL6 being electrically connected to a reference potential; and the balun 142b (a second balun) including the seventh transmission line TL7 and the eighth transmission line TL8, one end of the seventh transmission line TL7 being electrically connected to the other end of the fifth transmission line TL5, and another end of the seventh transmission line TL7 being configured to output the first signal RF10 to the emitter of the amplifier transistor 111 (the first amplifier transistor), the eighth transmission line TL8 being magnetically coupled to the seventh transmission line TL7, one end of the eighth transmission line TL8 being electrically connected to the other end of the sixth transmission line TL6 and to the reference potential, and another end of the eighth transmission line TL8 being configured to output the second signal RF20 to the emitter of the amplifier transistor 112 (the second amplifier transistor). This configuration enables a reduction in size of the circuit in the power amplifier module 100b, enables the power amplifier module 100b to be used at higher frequencies over wider frequency ranges, and enables impedance transformation by the power amplifier module 100b.
<6> The power amplifier module according to <1> or <2>, the power amplifier module 100c according to the present embodiment, further comprising: the converter including the primary coil and the secondary coil, one end of the primary coil being configured to receive the first input signal RFin10, and another end of the primary coil being configured to receive the second input signal, the first input signal RFin10 and the second input signal being differential signals, the primary coil having a center tap that is configured to receive power, the secondary coil being magnetically coupled to the primary coil, one end of the secondary coil being configured to output the first signal RF10 to the emitter of the amplifier transistor 111 (the first amplifier transistor), and another end of the secondary coil being configured to output the second signal RF20 to the emitter of the amplifier transistor 112 (the second amplifier transistor), the secondary coil having a center tap that is electrically connected to a reference potential. This configuration enables a reduction in size of the circuit in the power amplifier module 100c, enables the power amplifier module 100c to be used at higher frequencies over wider frequency ranges, and enables impedance transformation by the power amplifier module 100c. Additionally, this configuration can increase the gain of the power amplifier module 100c.
<7> The power amplifier module according to <1> or <2>, the power amplifier module 100d according to the present embodiment, further comprising: the converter 140d including the fourth transmission line transformer and the fifth transmission line transformer, the converter 140d being configured to output the first signal RF10 to the emitter of the amplifier transistor 111 (the first amplifier transistor) and to output the second signal RF20 to the emitter of the amplifier transistor 112 (the second amplifier transistor), the fourth transmission line transformer including the ninth transmission line TL9 and the tenth transmission line TL10, one end of the ninth transmission line TL9 being configured to receive the first input signal RFin10, the first input signal RFin10 and the second input signal RFin20 being differential signals, and another end of the ninth transmission line TL9 being electrically connected to the emitter of the amplifier transistor 111 (the first amplifier transistor), the tenth transmission line TL10 being magnetically coupled to the ninth transmission line TL9, one end of the tenth transmission line TL10 being electrically connected to the emitter of the amplifier transistor 112 (the second amplifier transistor), and another end of the tenth transmission line TL10 being electrically connected to a reference potential, the fifth transmission line transformer 142d including the eleventh transmission line TL11 and the twelfth transmission line TL12, one end of the eleventh transmission line TL11 being configured to receive the second input signal RFin20, and another end of the eleventh transmission line TL11 being electrically connected to the emitter of the amplifier transistor 112 (the second amplifier transistor) and to the reference potential, the twelfth transmission line TL12 being magnetically coupled to the eleventh transmission line TL11, one end of the twelfth transmission line TL12 being electrically connected to the other end of the tenth transmission line TL10, and another end of the twelfth transmission line TL12 being electrically connected to the emitter of the amplifier transistor 111 (the first amplifier transistor). This configuration enables a reduction in size of the circuit in the power amplifier module 100d, enables the power amplifier module 100d to be used at higher frequencies over wider frequency ranges, and enables impedance transformation by the power amplifier module 100d. Additionally, this configuration can increase the gain of the power amplifier module 100d.
<8> The power amplifier module according to <1> or <2>, the power amplifier module 100e according to the present embodiment, further comprising: the converter 140e including the sixth transmission line transformer 141e and the seventh transmission line transformer 142e, the converter 140e being configured to output the first signal RF10 to the emitter of the amplifier transistor 111 (the first amplifier transistor) and to output the second signal RF20 to the emitter of the amplifier transistor 112 (the second amplifier transistor), the sixth transmission line transformer 141e including the thirteenth transmission line TL13 line and the fourteenth transmission line, one end of the thirteenth transmission line TL13 being configured to receive the first input signal RFin10, the first input signal RFin10 and the second input signal RFin20 being differential signals, and another end of the thirteenth transmission line TL13 being electrically connected to the emitter of the amplifier transistor 111 (the first amplifier transistor), the fourteenth transmission line being magnetically coupled to the thirteenth transmission line TL13, one end of the fourteenth transmission line being electrically connected to the other end of the thirteenth transmission line TL13, and another end of the fourteenth transmission line being electrically connected to a reference potential, the seventh transmission line transformer including the fifteenth transmission line TL15 and the sixteenth transmission line TL16, one end of the fifteenth transmission line TL15 being configured to receive the second input signal RFin20, and another end of the fifteenth transmission line TL15 being electrically connected to the emitter of the amplifier transistor 112 (the second amplifier transistor), the sixteenth transmission line TL16 being magnetically coupled to the fifteenth transmission line TL15, one end of the sixteenth transmission line TL16 being electrically connected to the other end of the fifteenth transmission line TL15, and another end of the sixteenth transmission line TL16 being electrically connected to the other end of the fourteenth transmission line TL14 and to the reference potential. This configuration enables a reduction in size of the circuit in the power amplifier module 100d, enables the power amplifier module 100d to be used at higher frequencies over wider frequency ranges, and enables impedance transformation by the power amplifier module 100d. Additionally, this configuration can increase the gain of the power amplifier module 100d.
<9> The power amplifier module according to any one of <1> to <8>, the power amplifier module 100 according to the present embodiment, wherein the amplifier transistor 111 (the first amplifier transistor) and the amplifier transistor 112 (the second amplifier transistor) are symmetrically arranged across the capacitor 115 in plan view (in the Z direction), for each of the amplifier transistor 111 (the first amplifier transistor) and the amplifier transistor 112 (the second amplifier transistor), the base is positioned, in plan view (in the Z direction), between the capacitor 115 and a region that includes the emitter and the collector, the first bump Bump1 is disposed to overlap at least a portion of the emitter and the collector of the amplifier transistor 111 (the first amplifier transistor), and the second bump Bump2 is disposed to overlap at least a portion of the emitter and the collector of the amplifier transistor 112 (the second amplifier transistor). This configuration minimizes the interconnection length of each of the emitter, base, and collector of the amplifier transistors 111 and 112 in the power amplifier module 100, thereby improving the characteristics of the module.

The embodiment described above has been made for ease of understanding the present disclosure and should not be interpreted as limiting the present disclosure. The present disclosure may be modified or improved without departing from its spirit, and the present disclosure includes equivalents thereof. In other words, design alterations to the embodiment made in any manner by those skilled in the art fall within the scope of the present disclosure, provided that the alterations retain the features of the present disclosure. The features of the embodiment, including individual elements and arrangements thereof, are not limited to the illustrative examples described above and may be modified as appropriate.

What is claimed is:

1. A power amplifier module comprising:
a first resistor;
a first amplifier transistor having an emitter, a collector, and a base, the emitter being configured to receive a first signal, the collector being configured to output a first output signal, and the base being configured to receive a first bias through the first resistor;
a second resistor;
a second amplifier transistor having an emitter, a collector, and a base, the emitter being configured to receive a second signal, the collector being configured to output a second output signal, the base being configured to receive a second bias through the second resistor; and
a capacitor, a first end of the capacitor being electrically connected to the base of the first amplifier transistor, and a second end of the capacitor being electrically connected to the base of the second amplifier transistor, the capacitor being connected in parallel with the first resistor and the second resistor,
wherein the first signal and the second signal are differential signals.

2. The power amplifier module according to claim 1,
wherein the first amplifier transistor comprises a plurality of unit transistors connected in parallel,
wherein each of the unit transistors of the first amplifier transistor has an emitter, a collector, and a base, the emitter being configured to receive the first signal, the collector being configured to output the first output signal, and the base being configured to receive the bias through the first resistor,
wherein the second amplifier transistor comprises a plurality of unit transistors connected in parallel, and
wherein each of the unit transistors of the second amplifier transistor has an emitter, a collector, and a base, the emitter being configured to receive the second signal, the collector being configured to output the second output signal, and the base being configured to receive the bias through the second resistor.

3. The power amplifier module according to claim 1, further comprising:
a first balun comprising a primary coil and a secondary coil,
wherein the primary coil is configured to receive an input signal,
wherein the secondary coil is magnetically coupled to the primary coil,
wherein the secondary coil has a center tap that is electrically connected to a reference potential, and
wherein the secondary coil is configured to output the first signal to the emitter of the first amplifier transistor and to output the second signal to the emitter of the second amplifier transistor.

4. The power amplifier module according to claim 1, further comprising:
a converter comprising a first transmission line transformer and a second transmission line transformer,
wherein the converter is configured to output the first signal to the emitter of the first amplifier transistor and to output the second signal to the emitter of the second amplifier transistor,
wherein the first transmission line transformer comprises a first transmission line and a second transmission line,
wherein a first end of the first transmission line is configured to receive an input signal, and a second end of the first transmission line is electrically connected to the emitter of the first amplifier transistor,
wherein the second transmission line is magnetically coupled to the first transmission line, and a first end of the second transmission line is electrically connected to the emitter of the second amplifier transistor,
wherein the second transmission line transformer comprises a third transmission line and a fourth transmission line,
wherein a first end of the third transmission line is electrically connected to a reference potential, and a second end of the third transmission line is electrically connected to the emitter of the second amplifier transistor, and
wherein a first end of the fourth transmission line is electrically connected to a second end of the second transmission line, and a second end of the fourth transmission line is electrically connected to the emitter of the first amplifier transistor.

5. The power amplifier module according to claim 1, further comprising:
a third transmission line transformer comprising a fifth transmission line and a sixth transmission line;
a second balun comprising a seventh transmission line and an eighth transmission line,
wherein a first end of the fifth transmission line is configured to receive an input signal,
wherein a first end of the sixth transmission line is electrically connected to a second end of the fifth transmission line, and a second end of the sixth transmission line is electrically connected to a reference potential,
wherein a first end of the seventh transmission line is electrically connected to the second end of the fifth transmission line, and a second end of the seventh transmission line is configured to output the first signal to the emitter of the first amplifier transistor, and
wherein the eighth transmission line is magnetically coupled to the seventh transmission line, a first end of the eighth transmission line is electrically connected to the second end of the sixth transmission line and to the reference potential, and a second end of the eighth transmission line is configured to output the second signal to the emitter of the second amplifier transistor.

6. The power amplifier module according to claim 1, further comprising:
a converter comprising a primary coil and a secondary coil,
wherein a first end of the primary coil is configured to receive a first input signal, a second end of the primary coil is configured to receive a second input signal, the first input signal and the second input signal are differential signals, and the primary coil has a center tap that is configured to receive power, and
wherein the secondary coil is magnetically coupled to the primary coil, a first end of the secondary coil is configured to output the first signal to the emitter of the first amplifier transistor, a second end of the secondary coil is configured to output the second signal to the emitter of the second amplifier transistor, and the secondary coil has a center tap that is electrically connected to a reference potential.

7. The power amplifier module according to claim 1, further comprising:
a converter comprising a fourth transmission line transformer and a fifth transmission line transformer,
wherein the converter is configured to output the first signal to the emitter of the first amplifier transistor, and to output the second signal to the emitter of the second amplifier transistor,
wherein the fourth transmission line transformer comprises a ninth transmission line and a tenth transmission line,
wherein a first end of the ninth transmission line is configured to receive a first input signal, the first input signal and a second input signal are differential signals, and a second end of the ninth transmission line is electrically connected to the emitter of the first amplifier transistor,
wherein the tenth transmission line is magnetically coupled to the ninth transmission line, a first end of the tenth transmission line is electrically connected to the emitter of the second amplifier transistor, and a second end of the tenth transmission line is electrically connected to a reference potential,
wherein the fifth transmission line transformer comprises an eleventh transmission line and a twelfth transmission line,
wherein a first end of the eleventh transmission line is configured to receive the second input signal, and a second end of the eleventh transmission line is electrically connected to the emitter of the second amplifier transistor and to the reference potential, and
wherein the twelfth transmission line is magnetically coupled to the eleventh transmission line, a first end of the twelfth transmission line is electrically connected to the second end of the tenth transmission line, and a second end of the twelfth transmission line is electrically connected to the emitter of the first amplifier transistor.

8. The power amplifier module according to claim 1, further comprising:
a converter comprising a sixth transmission line transformer and a seventh transmission line transformer,
wherein the converter is configured to output the first signal to the emitter of the first amplifier transistor and to output the second signal to the emitter of the second amplifier transistor,
wherein the sixth transmission line transformer comprises a thirteenth transmission line and a fourteenth transmission line,
wherein a first end of the thirteenth transmission line is configured to receive a first input signal, the first input signal and a second input signal are differential signals, and a second end of the thirteenth transmission line is electrically connected to the emitter of the first amplifier transistor,
wherein the fourteenth transmission line is magnetically coupled to the thirteenth transmission line, a first end of the fourteenth transmission line is electrically connected to the second end of the thirteenth transmission line, and a second end of the fourteenth transmission line is electrically connected to a reference potential,
wherein the seventh transmission line transformer comprises a fifteenth transmission line and a sixteenth transmission line,
wherein a first end of the fifteenth transmission line is configured to receive the second input signal, and a second end of the fifteenth transmission line is electrically connected to the emitter of the second amplifier transistor, and
wherein the sixteenth transmission line is magnetically coupled to the fifteenth transmission line, a first end of the sixteenth transmission line is electrically connected to the second end of the fifteenth transmission line, and a second end of the sixteenth transmission line is electrically connected to the second end of the fourteenth transmission line and to the reference potential.

9. The power amplifier module according to claim 1,
wherein the first amplifier transistor and the second amplifier transistor are symmetrically arranged across the capacitor in plan view,
wherein for each of the first amplifier transistor and the second amplifier transistor, the base is between the capacitor and a region that includes the emitter and the collector in plan view,
wherein a first bump overlaps at least a portion of the emitter and the collector of the first amplifier transistor, and
wherein a second bump is overlaps at least a portion of the emitter and the collector of the second amplifier transistor.
